(19) United States
(12) Patent Application Publication
(10) Pub. No.: US 2010/0065870 A1
(43) Pub. Date: Mar. 18, 2010

(54) Light emitting device

(75) Inventors: Masahiro Arai, Hitachi (JP); Kazuyuki Ilzuka, Hitachi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: HITACHI CABLE, LTD., Tokyo (JP)

(21) Appl. No.: 12/461,009

(22) Filed: Jul. 29, 2009

(30) Foreign Application Priority Data
Sep. 12, 2008 (JP) 2008-234744

(51) Int. Cl. H01L 33/00

(52) U.S. Cl. 257/98; 257/E33.067

(57) ABSTRACT

A light emitting device includes a semiconductor multilayer structure having a first semiconductor layer of a first conductivity type, a second semiconductor layer of a second conductivity type, and an active layer. A reflecting layer is provided at one surface of the semiconductor multilayer structure and reflects a light emitted from the active layer. A supporting substrate is provided at an opposite side of the reflecting layer with respect to a side of the semiconductor multilayer structure and supports the semiconductor multilayer structure via a metal bonding layer. An adhesion layer is provided at a surface of the supporting substrate at an opposite side with respect to a side of the metal bonding layer. A back surface electrode of an alloy contacts with a surface of the adhesion layer at an opposite side with respect to a surface contacting to the supporting substrate.

The present application is based on Japanese Patent Application No. 2008-234744 filed on Sep. 12, 2008, the entire contents of which are incorporated herein by reference.

### BACKGROUND OF THE INVENTION

1. Field of the Invention

The present invention relates to a light emitting device, in more particular, to a light emitting device with high optical output which can be fabricated in high production yield.

2. Related Art

As a conventional light emitting device, a light emitting device comprising a silicon supporting substrate having an anode electrode on one surface, a metal reflecting layer provided on another surface of the silicon supporting substrate, a light transmitting film formed on the metal reflecting layer and being in ohmic-contact with the metal reflecting layer, a semiconductor multilayer comprising a p-type semiconductor layer provided on the light transmitting film and being in ohmic-contact with the light transmitting film, an n-type semiconductor layer, and an active layer sandwiched by the p-type semiconductor layer and the n-type semiconductor layer, and a cathode electrode provided on the semiconductor multilayer has been known. Japanese Patent Laid-Open No. 2005-175462 (JP-A 2005-175462) discloses one example of the conventional light emitting devices.

In the light emitting device disclosed by JP-A 2005-175462, the light transmitting film having an electrical conductivity is provided between the semiconductor multilayer and the metal reflecting layer, so that the light transmitting film is in ohmic-contact with both of the semiconductor multilayer and the metal reflecting layer, thereby suppressing alloying between the semiconductor multilayer and the metal reflecting layer. Therefore, it is possible to compose the metal reflecting layer with excellent light reflection characteristic, thereby providing the light emitting device with improved light emitting efficiency.

However, there is a following disadvantage in the light emitting device disclosed by JP-A 2005-175462. Namely, when manufacturing the light emitting device, each of a plurality of light emitting devices is divided by a dicing process. At this time, so-called “back surface chipping” such as chip and crack occurs in a back surface of the silicon supporting substrate, so that there is a restriction for improving the production yield of the light emitting device.

Therefore, an object of the invention is to provide a light emitting device with high production yield.

According to a feature of the invention, a light emitting device comprises:

a semiconductor multilayer structure having a first semiconductor layer of a first conductivity type, a second semiconductor layer of a second conductivity type different from the first conductivity type, and an active layer sandwiched between the first semiconductor layer and the second semiconductor layer;

a reflecting layer provided at a side of one surface of the semiconductor multilayer structure, the reflecting layer reflecting a light emitted from the active layer;

a supporting substrate provided at an opposite side of the reflecting layer with respect to the side of the semiconductor multilayer structure, the supporting substrate supporting the semiconductor multilayer structure via a metal bonding layer;

an adhesion layer provided at a surface of the supporting substrate at an opposite side with respect to a side of the metal bonding layer; and

a back surface electrode provided at and in contact with a surface of the adhesion layer at an opposite side with respect to a surface contacting to the supporting substrate, the back surface electrode comprising an alloy of different metals.

In the light emitting device, the semiconductor multilayer structure may be supported by the supporting substrate via a transparent layer provided on the reflecting layer, in which the transparent layer comprises an interface electrode penetrating through the transparent layer to electrically connect the semiconductor multilayer structure with the reflecting layer.

In the light emitting device, the adhesion layer may comprise Ti for fixing the supporting substrate with the back surface substrate.

In the light emitting device, the back surface electrode may have a hardness higher than a hardness of Au.

In the light emitting device, the back surface electrode may comprise an alloy of Au and at least one material selected from a group consisted of Al, Sn, Si, Zn, Be, and Ge.

### ADVANTAGES OF THE INVENTION

According to the light emitting device of the present invention, it is possible to provide a light emitting device with high production yield.

### BRIEF DESCRIPTION OF THE DRAWINGS

Next, the light emitting device in preferred embodiments according to the invention will be explained in conjunction with appended drawings, wherein:

FIG. 1A is a schematic longitudinal cross sectional view of a light emitting device in a preferred embodiment according to the invention;

FIG. 1B is a schematic top plan view of the light emitting device in the preferred embodiment according to the invention;

FIG. 2A is a cross sectional view showing a manufacturing process of the light emitting device in the preferred embodiment according to the invention;

FIG. 2B is a cross sectional view showing the manufacturing process of the light emitting device in the preferred embodiment according to the invention;

FIG. 3A is a cross sectional view showing the manufacturing process of the light emitting device in the preferred embodiment according to the invention;

FIG. 3B is a cross sectional view showing the manufacturing process of the light emitting device in the preferred embodiment according to the invention;

FIG. 4 is a cross sectional view showing the manufacturing process of the light emitting device in the preferred embodiment according to the invention;

FIG. 5A is a cross sectional view showing the manufacturing process of the light emitting device in the preferred embodiment according to the invention;

FIG. 5B is a cross sectional view showing the manufacturing process of the light emitting device in the preferred embodiment according to the invention;

FIG. 6A is a cross sectional view showing the manufacturing process of the light emitting device in the preferred embodiment according to the invention;

FIG. 6B is a cross sectional view showing the manufacturing process of the light emitting device in the preferred embodiment according to the invention;

FIG. 7 is a cross sectional view showing the manufacturing process of the light emitting device in the preferred embodiment according to the invention;

FIG. 8 is a cross sectional view showing the manufacturing process of the light emitting device in the preferred embodiment according to the invention;

FIG. 9 is a cross sectional view showing the manufacturing process of the light emitting device in the preferred embodiment according to the invention;

FIG. 10 is a cross sectional view showing the manufacturing process of the light emitting device in the preferred embodiment according to the invention; and

FIG. 11 is a cross sectional view showing the manufacturing process of the light emitting device in the preferred embodiment according to the invention.

### DETAILED DESCRIPTION OF THE PREFERRED EMBODIMENT

Next, the preferred embodiment according to the present invention will be explained in more detail in conjunction with the appended drawings.

### (The Preferred Embodiment)

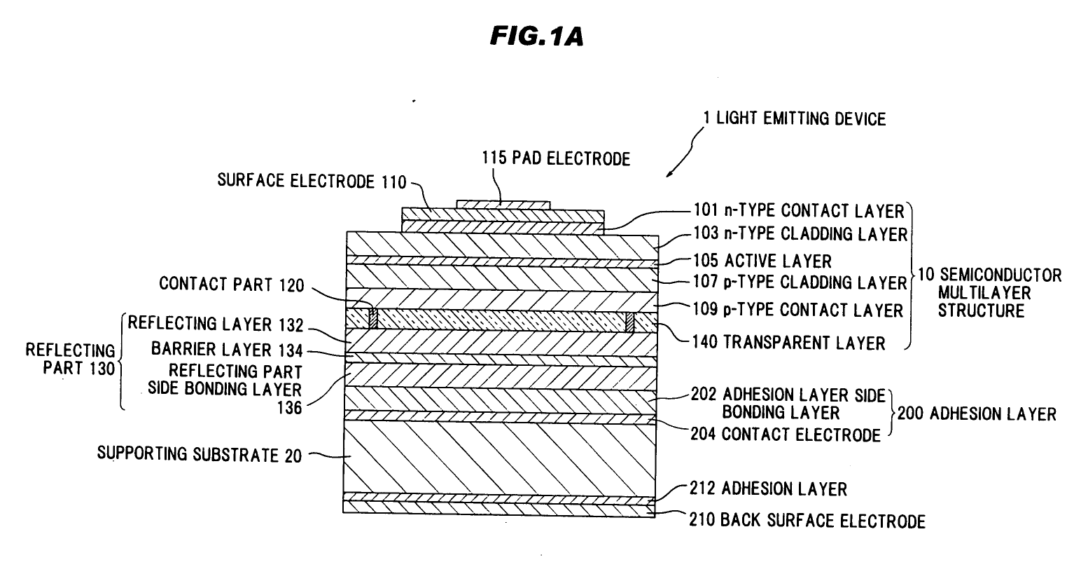

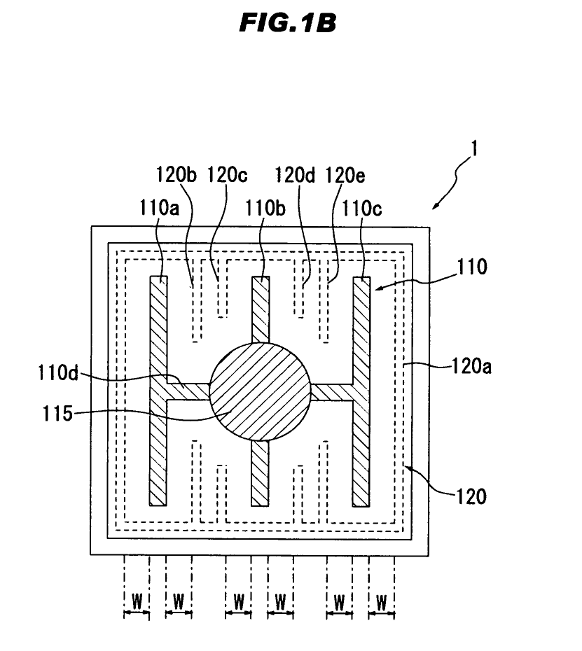

FIG. 1A is a schematic longitudinal cross sectional view of a light emitting device in a preferred embodiment according to the invention. FIG. 1B is a schematic top plan view of the light emitting device in the preferred embodiment according to the invention.

### (Outline of a Structure of the Light Emitting Device 1)

With referring to FIG. 1A, a light emitting device 1 comprises a semiconductor multilayer structure 10 having an active layer 105 which emits a light with a predetermined wavelength, a surface electrodes 110 electrically connected to a region of a part of a surface of the semiconductor multilayer structure 10, a pad electrode 115 provided on a surface of the surface electrode 110 as a wire-bonding pad, a contact part 120 as an interface electrode being in ohmic-contact with a part of another surface of the semiconductor multilayer structure 10, a transparent layer 140 provided on another surface of the semiconductor multilayer structure 10 except a region where the contact part 120 is provided, and a reflecting part 130 provided on a surface of the contact part 120 and the transparent layer 140 at an opposite side with respect to another surface contacting with the semiconductor multi layer structure 10.

Further, the light emitting device 1 further comprises an adhesion layer 200 having an electrical conductivity and provided on a surface of the reflecting part 130 at an opposite side with respect to another surface contacting with the contact part 120 and the transparent layer 140, and a supporting substrate 20 having an electrical conductivity and provided on a surface of the adhesion layer 200 at an opposite side with respect to another surface contacting with the reflecting part 130, and a back surface electrode 210 provided on a surface of the supporting substrate 20 at an opposite side with respect to another surface contacting with the adhesion layer 200 via an adhesion layer 212. The back surface electrode 210 comprises an alloy material containing gold (Au) and having a higher hardness than a hardness of Au per se.

In addition, the semiconductor multilayer structure 10 in the light emitting device 1 in the preferred embodiment comprises a p-type contact layer 109 provided in contact with the contact part 120 and the transparent layer 140, a p-type cladding layer 107 provided as a second semiconductor layer with a second conductivity type on a surface of the p-type contact layer 109 at an opposite side with respect to another surface contacting with the transparent layer 140, the active layer 105 provided on a surface of the p-type cladding layer 107 at an opposite side with respect to another surface contacting with the p-type contact layer 109, an n-type cladding layer 103 provided as a first conductivity type first semiconductor layer provided on a surface of the active layer 105 at an opposite side with respect to another surface contacting with the p-type cladding layer 107, and an n-type contact layer 101 provided on a region of a surface of the n-type cladding layer 103 at an opposite side with respect to another surface contacting with the active layer 105. Herein, the surface of the semiconductor multilayer structure 10 at the opposite side with respect to another surface contacting with the transparent layer 140 is the light extracting surface of the light emitting device 1 in the preferred embodiment. More concretely, a part of the n-type cladding layer 103 at the opposite side with respect to another surface contacting with the active layer 105 is provided as the light extracting surface.

Further, the reflecting part 130 comprises a reflecting layer 132 provided in contact with the contact part 120 and the transparent layer 140, a barrier layer 134 provided on a surface of the reflecting layer 132 at an opposite side with respect to another surface contacting with the contact part 120 and the transparent layer 140, and a bonding layer 136 provided as one bonding layer on a surface of the barrier layer 134 at an opposite side with respect to another surface contacting with the reflecting layer 132. The adhesion layer 200 comprises a bonding layer 202 as another bonding layer electrically and mechanically bonded to the bonding layer 136 of the reflecting part 130, and a contact electrode 204 provided on a surface of the bonding layer 202 at an opposite side with respect to another surface contacting with the reflecting layer 130.

In addition, as shown in FIG. 1B, the light emitting device 1 in the preferred embodiment is formed to be substantially square in a top plan view. As an example, plane dimensions of the light emitting device 1 are a vertical length of 330 μm and a lateral length of 330 μm, respectively. Further, a thickness of the light emitting device 1 is formed to be about 210 μm. Still further, for example, the light emitting device 1 in the preferred embodiment may be composed as a light emitting device with a large-scale chip size in which the plane dimensions are 500 μm×500 μm or more.

### (Detailed Structure of the Surface Electrode 110 and the Contact Part 120)

The surface electrode 110 and the contact part 120 will be explained in more detail. The surface electrode 110 comprises a circular electrode and a plurality of narrow electrodes to be provided on the n-type contact layer 101. For example, the surface electrode 110 comprises a narrow electrode 110a located in vicinity of one side of the light emitting device 1 formed to be substantially rectangular in top plan view, the narrow electrode 110a being substantially horizontal with the one side of the light emitting device 1, a narrow electrode 110c located in vicinity of an opposite side of the one side of the light emitting device 1, the narrow electrode 110c being substantially horizontal with the opposite side, and a narrow electrode 110b provided between the narrow electrode 110a and the narrow electrode 110c to be substantially equidistant from both of the narrow electrode 110a and the narrow electrode 110c, the narrow electrode 110b being substantially horizontal with the narrow electrode 110a and the narrow electrode 110c.

The surface electrode 110 further comprises a narrow electrode 110d extending along a direction substantially perpendicular to longitudinal directions of the narrow electrode 110a, the narrow electrode 110b and the narrow electrode 110c, the narrow electrode 110d being provided to be in contact with the narrow electrodes 110a, 110b, and 110c in the substantially middle of these narrow electrodes 110a, 110b, and 110c. In addition, the surface electrode 110 comprises a circular electrode in a region including an intersection point of the narrow electrode 110b and the narrow electrode 110d. The circular electrode is not shown in FIG. 1B, since the circular electrode is located right under the pad electrode 115. The pad electrode 115 is provided at a position in which a center of the light emitting device 1 is substantially coincident with a center of the pad electrode 115. In other words, the pad electrode 115 is provided right above the circular electrode.

Next, the contact part 120 is provided with a unitary without a cutting part in the top plan view within an opening located in a part other than a region of the transparent layer 140 right under the surface electrode 110 in the top plan view. For example, the contact part 120 comprises an outer periphery part 120a having a shape provided along an outer periphery of the light emitting device 1, and a narrow linear part 120b extending from one side of the outer periphery part 120a toward a center in a predetermined length, the narrow liner part 120b being in contact with the outer periphery part 120a at one end, and a narrow linear part 120c provided to be adjacent to the narrow linear part 120b at a position closer to the side of the pad electrode 115 than the narrow linear part 120b, the narrow linear part 120c being formed in a length shorter than a length of the narrow linear part 120b.

The contact part 120 further comprises a narrow linear part 120d and a narrow linear part 120e, which are provided in symmetrical positions to the narrow linear part 120b and the narrow linear part 120c with respect to a center line of the narrow electrode 110b facing to a longitudinal direction of the narrow electrode 110b as an axis of symmetry (not shown). The contact part 120 further comprises a plurality of narrow parts, which are provided in symmetrical positions to the narrow linear part 120b and the narrow linear part 120e with respect to a center line of the narrow electrode 110d as an axis of symmetry.

The surface electrode 110 and the contact part 120 are arranged such that the surface electrode 110 does not superpose the contact part 120 in the top plan view. For example, the narrow linear part 120b and the narrow linear part 120c are located between the narrow electrode 110a and the narrow electrode 110b. In addition, each of the narrow linear part 120b and the narrow linear part 120c is formed in such a length that does not contact with the narrow electrode 110d. Similarly, the narrow linear part 120d and the narrow linear part 120e are located between the narrow electrode 110b and the narrow electrode 110c. In addition, each of the narrow linear part 120d and the narrow linear part 120e is formed in such a length that does not contact with the narrow electrode 110d. Herein, when a minimum length from an outer edge of the narrow electrode of the surface electrode 110 to an outer edge of the contact part 120 is defined as “W” in the top plan view of the light emitting device 1, the surface electrode 110 and the contact part 120 are arranged such that each W is substantially equal to each other. In addition, a length between each of front edges of the narrow electrodes 110a-110c and the edge of the contact part 120 is W or more.

The circular electrode of the surface electrode 110 is formed to have a diameter of at least 75 μm in accordance with a diameter of a ball section of a wire comprising a metallic material such as Au, which is connected to the pad electrode 115 provided on the circular electrode. As an example, the circular electrode of the surface electrode 110 is formed to have a circular shape with a diameter of 100 μm. The narrow electrodes 110a-110d of the surface electrode 110 are formed to have a linear shape with a width of 10 μm. Furthermore, the contact part 120 is provided at a part of the surface of the p-type contact layer 109, except a region right under the surface electrode 110. As an example, each of the narrow linear parts is formed to have a width of 5 μm. More concretely, the contact part 120 is formed within the opening penetrating through the transparent layer 140, to electrically connect the semiconductor multilayer structure 10 with the reflecting layer 132. As an example, the contact part 120 comprises a metallic material including Au and Zn.

### (Semiconductor Multilayer Structure 10)

The semiconductor multilayer structure 10 in the preferred embodiment comprises an AlGaInP based compound semiconductor which is a III-V group compound semiconductor. More concretely, the semiconductor multilayer structure 10 has a configuration in which the active layer 105 comprising an undoped AlGaInP based compound semiconductor bulk which is not doped with a dopant of an impurity is sandwiched between the n-type cladding layer 103 comprising an n-type AlGaInP and the p-type cladding layer 107 comprising a p-type AlGaInP.

The active layer 105 emits the light with the predetermined wavelength when the electric current is supplied from the outside to the active layer 105. For example, the active layer 105 comprises a compound semiconductor which emits a red light with a wavelength of around 630 nm. As an example, the active layer 105 comprises an undoped (Al_{0.1}Ga_{0.9)}_{0.5}In_{0.5}P layer. The n-type cladding layer 103 contains a predetermined concentration of an n-type dopant such as Si and Se. As an example, the n-type cladding layer 103 comprises a Si-doped (Al_{0.7}Ga_{0.3})_{0.5}In_{0.5}P layer. The p-type cladding layer 107 contains a predetermined concentration of a p-type dopant such as Zn and Mg. As an example, the p-type cladding layer 107 comprises a Mg-doped (Al_{0.7}Ga_{0.3})_{0.5}In_{0.5}P layer.

Furthermore, the p-type contact layer 109 of the semiconductor multilayer structure 10 comprises a p-type GaP layer doped with Mg at a predetermined concentration. The n-type contact layer 101 comprises a GaAs layer doped with Si at a predetermined concentration. The n-type contact layer 101 is provided at a region in which at least the surface electrode 110 is provided on an upper surface of the n-type cladding layer 103.

### (Transparent Layer 140)

The transparent layer 140 is provided at a region where the contact part 120 is not provided on the surface of the p-type contact layer 109. The transparent layer 140 comprises a material which transmits a light with the wavelength of the light emitted from the active layer 105. For example, the transparent layer 140 comprises a transparent material with respect to the light emitted from the active layer 105. As an example, the transparent layer 140 comprises a transparent dielectric layer such as SiO₂, TiO₂, and SiNₓ. In addition, the transparent layer 140 has a function as a current blocking layer for blocking the electric current flow in a part where the transparent layer 140 is provided. An opening penetrates through a predetermined region, in which the contact part 120 of the transparent layer 140 is formed, along a thickness direction, and the opening is filled with a metallic material to provide the contact part 120.

### (Reflecting Part 130)

The reflecting layer 132 of the reflecting part 130 comprises a conductive material having a high reflectivity with respect to the light emitted from the active layer 105. As an example, the reflecting layer 132 comprises a conductive material having a reflectivity of 80% or more with respect to the light emitted from the active layer 105. The reflecting layer 132 reflects the light that is emitted from the active layer 10s and reached the reflecting layer 132 toward the active layer 105. For example, the reflecting layer 132 comprises a metallic material such as Al, Au, and Ag, or alternatively an alloy including at least one selected from these metallic materials. As an example, the reflecting layer 132 may comprise Au with a predetermined film thickness. The barrier layer 134 of the reflecting part 130 comprises a metallic material such as Ti and Pt. As an example, the barrier layer 134 may comprise Pt with a predetermined film thickness. The barrier layer 134 suppresses the material composing the bonding layer 136 from propagating (dispersing) into the reflecting layer 132. In addition, the bonding layer (reflecting part side bonding layer) 136 comprises a material that is electrically and mechanically bonding to the bonding layer (adhesion layer side bonding layer) 202 of the adhesion layer 200. As an example, the bonding layer 136 may comprise Au with a predetermined film thickness.

### (Supporting Substrate 20)

The supporting substrate 20 comprises an electrically conductive material. For example, the supporting substrate 20 may comprise a semiconductor substrate such as p-type or n-type conductive Si substrate. In this preferred embodiment, a Si substrate having a resistivity of 0.01 Ω·cm or less is used. In addition, a face orientation of the Si substrate as the supporting substrate 20 is not limited and may be any orientation.

The bonding layer 202 of the adhesion layer 200 may comprise Au with a predetermined thickness, similarly to the bonding layer 136 of the reflecting part 130. In addition, the contact electrode 204 comprises a metallic material that is electrically connected to the supporting substrate 20 and suppresses the material composing the bonding layer 202 from propagating to the side of the support substrate 20. For example, the contact electrode 204 may comprise Ti with a predetermined thickness.

The back surface electrode 210 comprises a material that is electrically connected to the supporting substrate 20. The back surface electrode 210 is provided on a back surface of the supporting substrate 20 (i.e. a surface opposite to a surface where the contact electrode 204 is provided) via a thin adhesion layer 212 that is provided between the back surface electrode 210 and the supporting substrate 20. The back surface electrode 210 comprises e.g. an alloy layer comprising Au and at least one material selected from a group consisted of Al, Sn, Si, Zn, Be and Ge. Resistance properties for oxidation and the like are improved by including Au in the back surface electrode 210. In addition, the adhesion layer 212 comprises a metallic material that is hardly alloyed with the supporting substrate 20 and has a good adhesion property with the supporting substrate 20. As an example, the adhesion layer 212 may comprise Ti. In addition, the light emitting device 1 is mounted at a predetermined position of a stem comprising a metallic material such as Al and Cu, by using a conductive bonding material such as Ag pates, or a eutectic material such as AuSn, in the state that a side of the back surface electrode 210 is located downwardly.

### (Variations)

The light emitting device 1 in the preferred embodiment emits the light including red at a wavelength of 630 nm. However, the wavelength of the light emitted from the light emitting device 1 is not limited to this wavelength. Further, it is possible to form the light emitting device 1 which emits a light in a predetermined wavelength range by controlling the structure of the active layer 105 of the semiconductor multilayer structure 10. The active layer 105 emits the light within the wavelength range of e.g. orange light, yellow light, and green light.

In the semiconductor multilayer structure 10 of the light emitting device 1, a conductivity type of the compound semiconductor layer composing the semiconductor multilayer structure 10 may be changed to a conductivity type opposite to the conductivity type in this preferred embodiment. For example, the conductivity type of the n-type contact layer 101 and the n-type cladding layer 103 may be changed to p-type, and the conductivity type of the p-type cladding layer 107 and the p-type contact layer 109 may be changed to n-type.

A shape of the surface electrode 110 in the top plan view is not limited to the shape in the preferred embodiment, and may be another shape such as rectangular, rhombic, and polygonal in the top plan view. Furthermore, the contact part 120 is formed to have the unitary shape without any cutting part. In the variation, however, the contact part 120 comprising plural regions may be formed by forming a cutting part in a part of the contact part 120. For example, the contact part 120 may be formed as a dot shape. In addition, a pure Au layer, a pure Pt layer or the like having a thickness of several nanometers (nm) be formed on an outermost surface of the back surface electrode 210.

The plane dimensions of the light emitting device 1 are not limited to that in the preferred embodiment. For example, the plane dimensions of the light emitting device 1 may be designed such that the vertical length is greater than 1 mm and the lateral length is greater than 1 mm. In addition, the vertical length and the lateral length may be changed appropriately in accordance with application of the light emitting device 1. As an example, when the plane dimensions of the light emitting device 1 are designed such that the vertical length is shorter than the lateral length, the shape of the light emitting device 1 in the top plan view is substantially rectangular.

The active layer 105 may comprise a quantum well structure. The quantum well structure may comprise a single quantum well structure, a multiquantum well structure or a strain multiquantum well structure.

### (Process for Fabricating the Light Emitting Device 1)

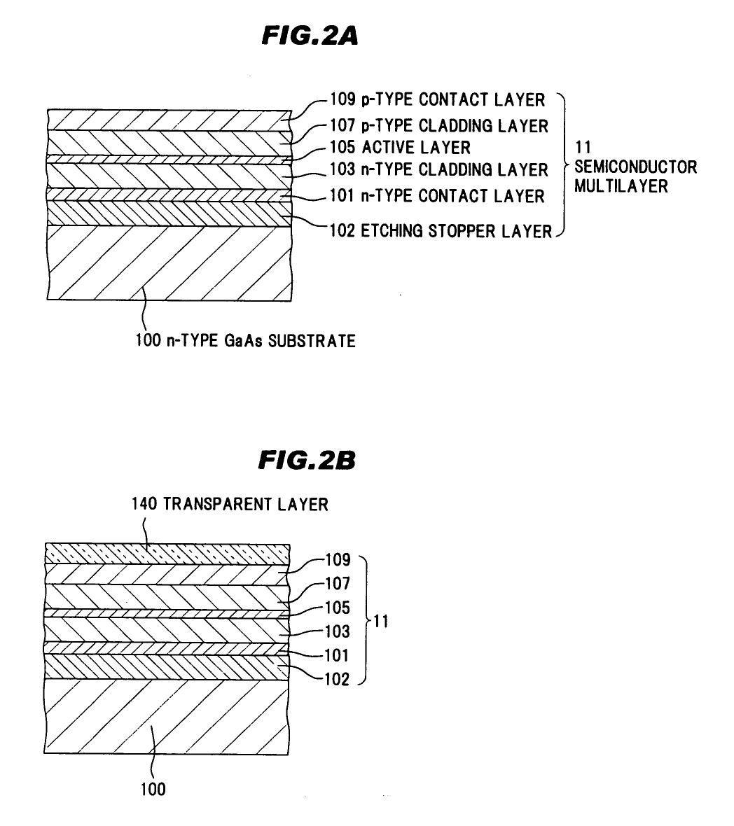

FIGS. 2A, 2B, 3A, 3B, 4, 5A, 5B, 6A, 6B, 7, 8, 9, 10 and 11 are diagrams showing a process for fabricating the light emitting device in the first preferred embodiment.

At first, as shown in FIG. 2A, an AlGaInP based semiconductor multilayer 11 including plural compound semiconductor layers comprises is grown by Metal Organic Vapor Phase Epitaxy (MOVPE) on an n-type GaAs substrate 100, for example. More concretely, the etching stopper layer 102 comprising an undoped (Al_{0.7}Ga_{0.3})_{0.5}In_{0.5}P, an n-type contact layer 101 comprising a Si-doped n-type GaAs, the n-type cladding layer 103 comprising a Si-doped n-type (Al_{0.7}Ga_{0.3})_{0.5}In_{0.5}P, the active layer 105 comprising an undo (Al_{0.1}Ga_{0.9})_{0.5}In_{0.5}P, and the p-type cladding layer 107 comprising a Mg-doped p-type (Al_{0.7}Ga_{0.3)}_{0.5}In_{0.5}P, and the p-type contact layer 109 comprising a Mg-doped p-type GaP are grown in this order on the n-type GaAs substrate 100, to provide an epitaxial wafer in which the semiconductor multilayer 11 is formed on the n-type GaAs substrate 100.

As sources used in the MOVPE method, an organometallic compound such as trimethylgallium (TMGa), triethylgallium (TEGa), trimethylaluminum (TMAl), and trimethylindium (TMIn), and a hydride gas such as arsin (AsH₃) and phosphine (PH₃) may be used. Further, as a source of the n-type dopant, disilane (Si₂H₆) may be used. As a source of the p-type dopant, biscyclopentadienyl magnesium (Cp₂Mg) may be used.

Further, as the source of the n-type dopant, hydrogen selenide (H₂Se), monosilane (SiH₄), diethyl tellurium (DETe) or dimethyl tellurium (DMTe) may be used. As the source of the p-type dopant, dimethylzinc (DMZn) or diethylzinc (DEZn) may be used.

In addition, the semiconductor multilayer 11 may be grown on the n-type GaAs substrate 100 by using Molecular Beam Epitaxy (MBE) method. In addition, the GaN system semiconductor multilayer 11 may be grown by using Halide Vapor Phase Epitaxy (HVPE) method.

Next, as shown in FIG. 2B, after taking out the epitaxial wafer formed as shown in FIG. 2A of the MOVPE equipment, a transparent layer 140 is formed on the surface of p-type contact layer 109. More concretely, a SiO₂ film as the transparent layer 140 is formed on the surface of p-type contact layer 109 by plasma Chemical Vapor Deposition (CVD) equipment. Herein, the transparent layer 140 may be formed by vacuum deposition method.

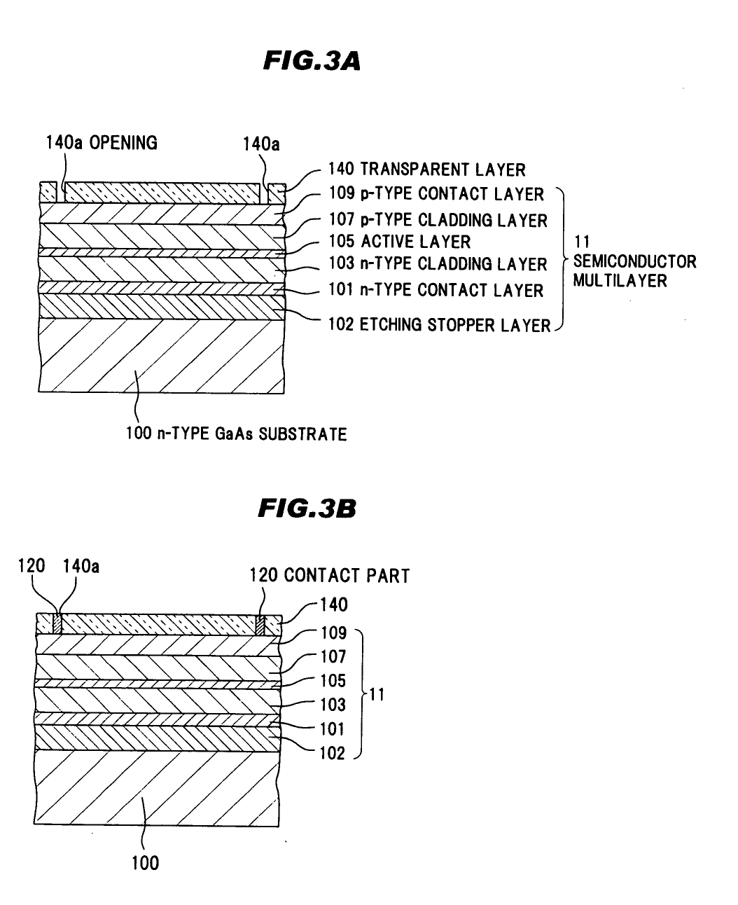

Next, as shown in FIG. 3A, openings 140a are formed at the transparent layer 140 by using photolithography method and etching method. For example, a photoresist pattern having a groove at a region corresponding to the opening 140a is formed on the transparent layer 140. The openings 140a are formed to penetrate through the transparent layer 140 from a surface of the transparent layer 140 until an interface between the p-type contact layer 109 and the transparent layer 140. More concretely, the openings 140a are formed at the transparent layer 140 by removing regions where the photoresist pattern is not formed of the transparent layer 140 with use of a fluorinated acid based etchant diluted with demineralized water. The openings 140a are formed at regions where the contact parts 120 will be provided as explained in FIG. 1B.

Subsequently, as shown in FIG. 3B, a AuZn alloy (Au:Zn=95 wt %:5 wt %) which is a material composing the contact part 120 is formed within the opening 140a by using the vacuum deposition method and lift-off method. For example, AuZn is vacuum-evaporated within the opening 140a by using the photoresist pattern for forming the opening 140a as a mask, to provide the contact part 120 comprising AuZn as shown in FIG. 3B. The detailed explanation of the configuration of the contact part 120 is omitted here, since the configuration of the contact part 120 is explained in detail in the “Detailed structure of the surface electrode 110 and the contact part 120”.

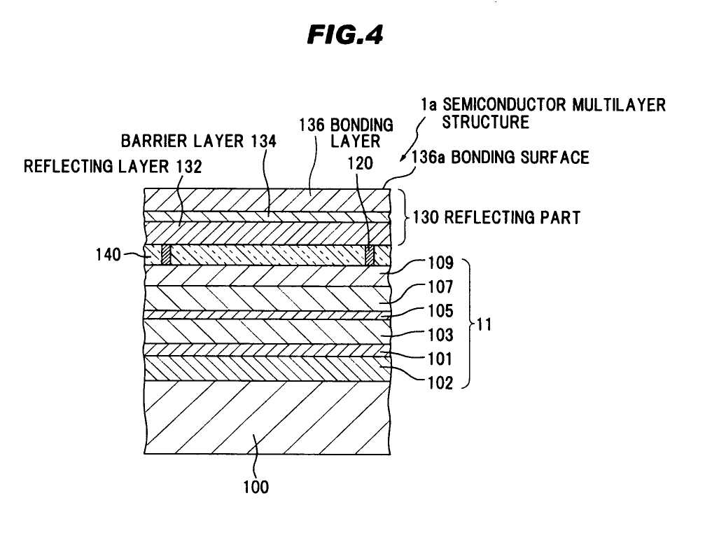

Next, as shown in FIG. 4, an Al layer as the reflecting layer 132, a Pt layer as the barrier layer 134, and a Au layer as the bonding layer 136 are formed by using the vacuum deposition method or sputtering method, to provide a semiconductor multilayer structure 1a. Herein, as the reflecting layer 132, a material having a high reflectivity with respect to the wavelength of the light emitted from the active layer 105 may be selected.

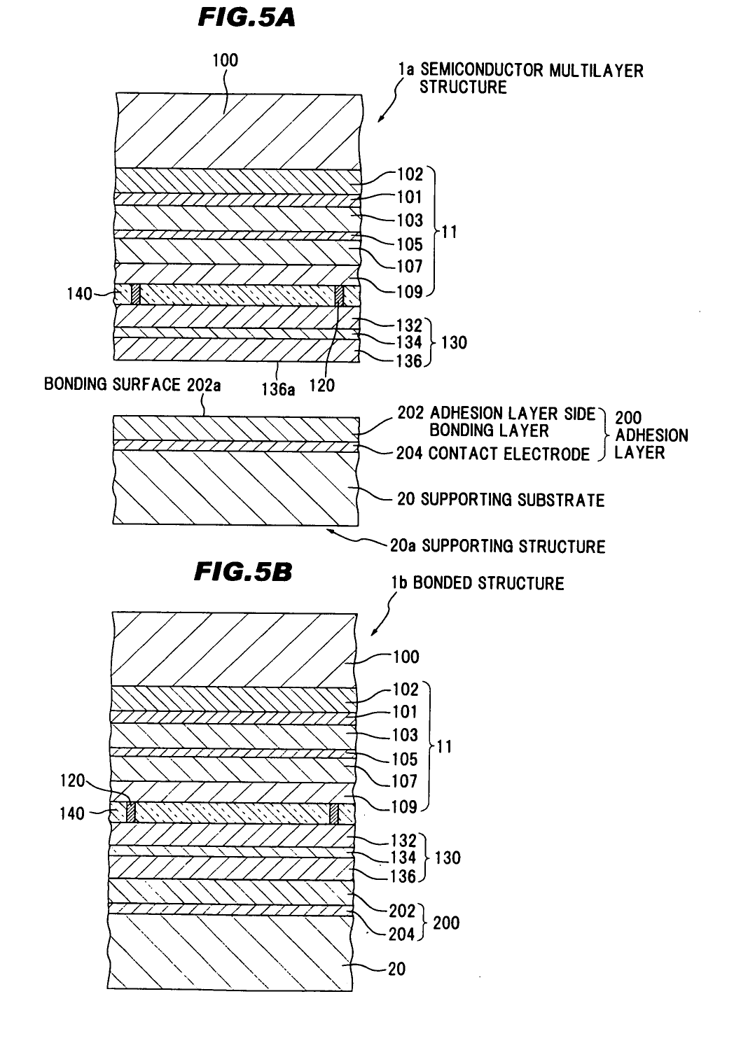

Next, as shown in FIG. 5A, Ti as the contact electrode 204 and Au as the bonding layer 202 are formed in this order on the Si substrate as the supporting substrate 20 by using the vacuum deposition method, to provide a supporting structure 20a. Successively, a bonding surface 136a which is a surface of the bonding layer 136 of the semiconductor multilayer structure 1a and a bonding surface 202a which is a surface of the bonding layer 202 of the supporting structure 20a are stuck to be facing to each other, and held in this state by a jig made from carbon or the like.

Next, the jig holding the state that the semiconductor multilayer structure 1a is stuck on the supporting structure 20a is introduced in a wafer bonding equipment. Then, the wafer bonding equipment is depressurized to a predetermined pressure. As an example, the predetermined pressure is set as 1.333 Pa (0.01 Torr). Then, a pressure is applied through the jig to the semiconductor multilayer structure 1a and the supporting structure 20a overlapped with each other. As an example, a pressure of 15 kgf/cm² is applied. Next, the jig is heated to a predetermined temperature with a predetermined rate of temperature elevation.

More concretely, the temperature of the jig is raised to 350° C. After the temperature of the jig reached to 350° C., the jig is held at the temperature of 350° C. for about one hour. Then, the jig is gradually cooled and the temperature of the jig is decreased enough, for example, to the room temperature. After the temperature of the jig fell, the pressure applied to the jig is left open. After the pressure in the wafer bonding equipment is increased to an atmospheric pressure, the jig is taken out from the equipment. According to this process, as shown in FIG. 5B, a bonded structure 1b, in which the semiconductor multilayer structure 1a and the supporting structure 20a are mechanically bonded with each other between the bonding layer 136 and the bonding layer 202, is formed.

In this preferred embodiment, the semiconductor multilayer structure 1a comprises the barrier layer 134. Therefore, even though the semiconductor multilayer structure 1a and the supporting structure 20a are bonded to each other by using the bonding surface 136a and the bonding surface 202a, it is possible to suppress the diffusion of the material composing the bonding layer 136 and the bonding layer 202 into the reflecting layer 132, thereby suppressing the deterioration of the reflecting property of the reflecting layer 132.

Next, the bonded structure 1b is stuck by an attaching wax on a jig of a lapping equipment. More concretely, a surface at a side of the supporting substrate 20 is attached to the jig. Then, the n-type GaAs substrate 100 of the bonded structure 1b is lapped to have a predetermined thickness. Subsequently, the bonded structure 1b after lapping is detached from the jig of the lapping equipment, and the wax bonded to the surface of the supporting substrate 20 is removed by cleaning.

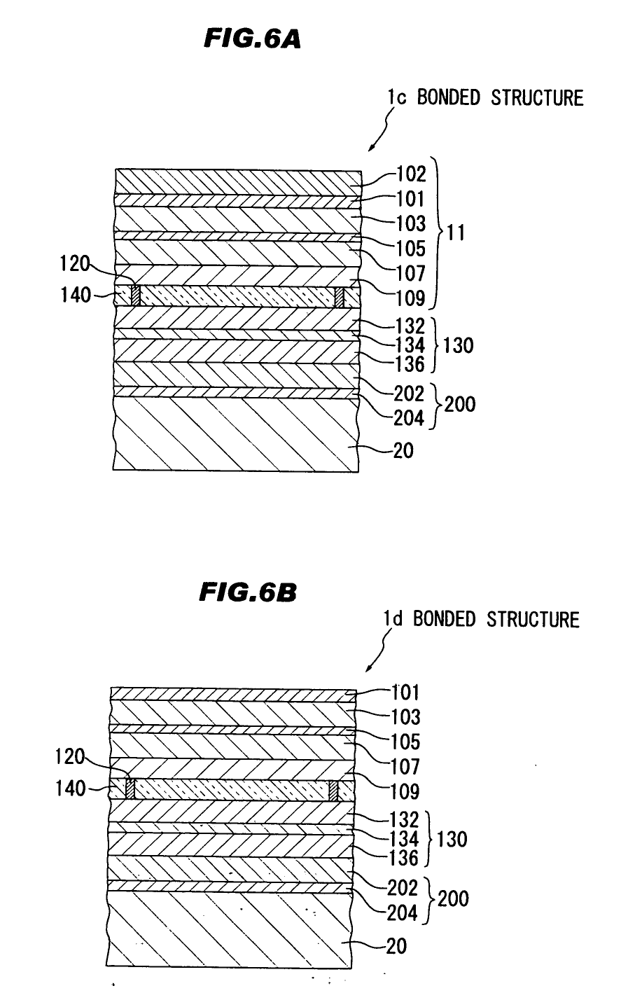

Thereafter, as shown in FIG. 6A, the n-type GaAs substrate 100 is completely removed from the bonded structure 1b after lapping by selective etching using an etchant for GaAs etching, to form a bonded structure 1c in which an etching stopper layer 102 is exposed. As the etchant for GaAs etching, a mixture of ammonia water and hydrogen peroxide water may be used. In addition, the n-type GaAs substrate 100 may be completely removed by selective etching without lapping the n-type GaAs substrate 100.

Subsequently, as shown in FIG. 6B, the etching stopper layer 102 is removed from the bonded structure 1c by etching with use of a predetermined etchant to provide the bonded structure 1d in which the etching stopper layer 102 is removed. When the etching stopper layer 102 comprises an AlGaInP based compound semiconductor, an etchant including hydrochloric acid may be used. According to this step, a surface of the n-type contact layer 101 is exposed to the outside.

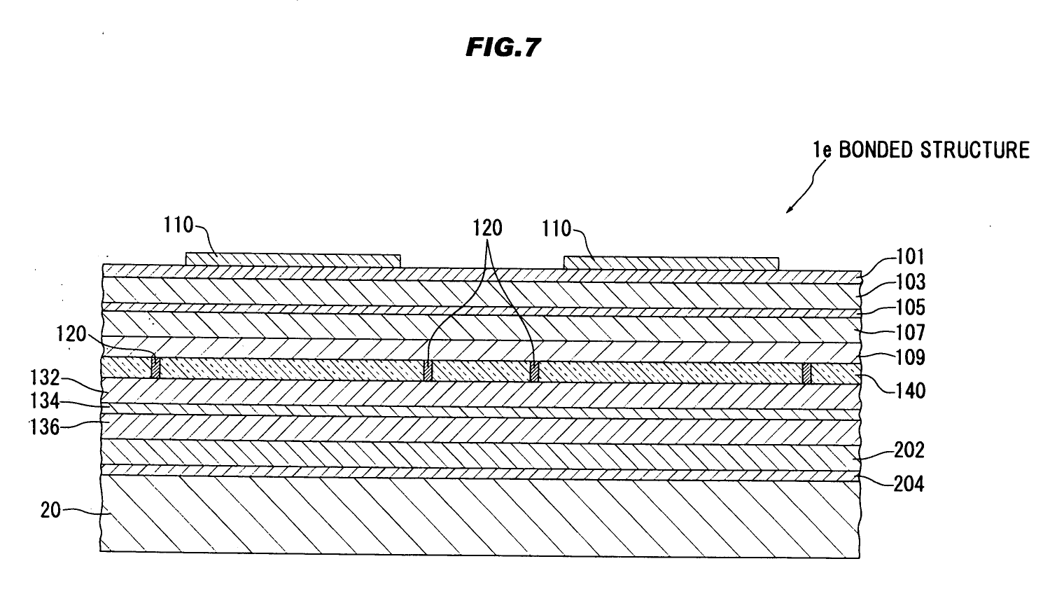

Successively, the surface electrode 110 is formed at a predetermined position on the surface of the n-type contact layer 101 by the photo lithography method and the vacuum deposition. The surface electrode 110 comprises the circular electrode having a diameter of 100 μm and the narrow electrodes each having a width of 10 μm. The surface electrode 110 may be formed, for example, by depositing AuGe, Ni, and Au on the n-type contact layer 101 in this order. For this case, the surface electrode 110 is formed not to be located right above the contact part 120. The detailed explanation of the configuration of the surface electrode 110 is omitted here, since the configuration of the surface electrode 110 is explained in detail in the “Detailed structure of the surface electrode 110 and the contact part 120”. According to this process, a bonded structure 1e having the surface electrode 110 is formed as shown in FIG. 7.

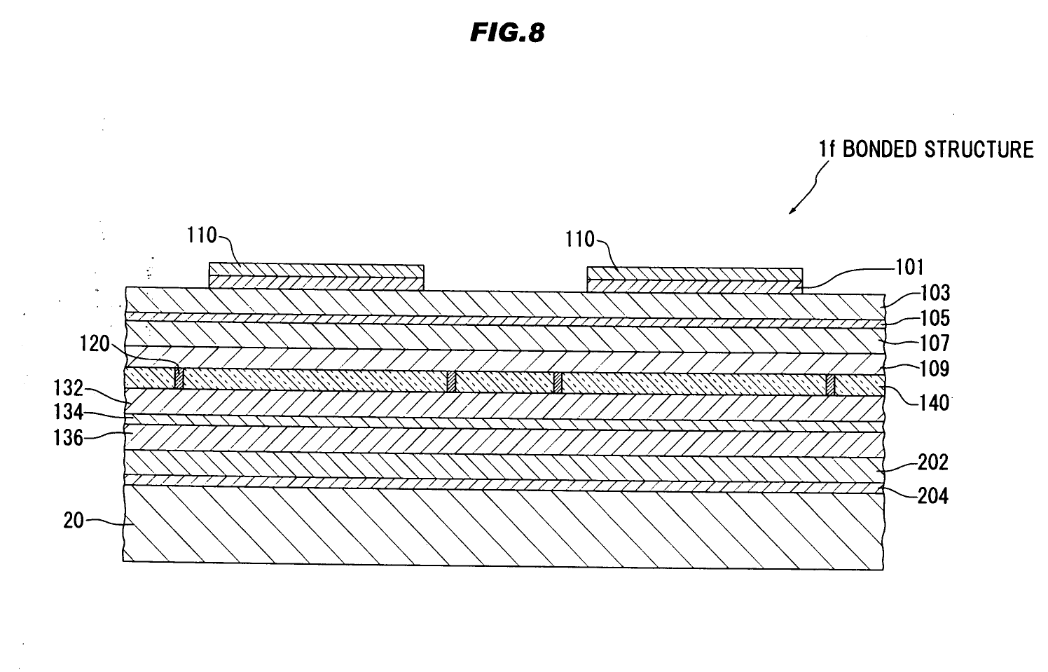

Next, as shown in FIG. 8, the etching treatment using a mixture of sulfuric acid and hydrogen peroxide water is performed on the n-type contact layer 101, except a part of the n-type contact layer 101 provided right under the surface electrode 110, with using the surface electrode 110 formed in the step shown in FIG. 7 as a mask, thereby providing a bonded structure 1f. By using the above mixture, it is possible to selectively etch the n-type contact layer 101 comprising GaAs as against the n-type cladding layer 103 comprising the n-type (Al_{0.7}Ga_{0.3})_{0.5}In_{0.5}P. Therefore, in the bonded structure If, a surface of the n-type cladding layer 103 is exposed to the outside.

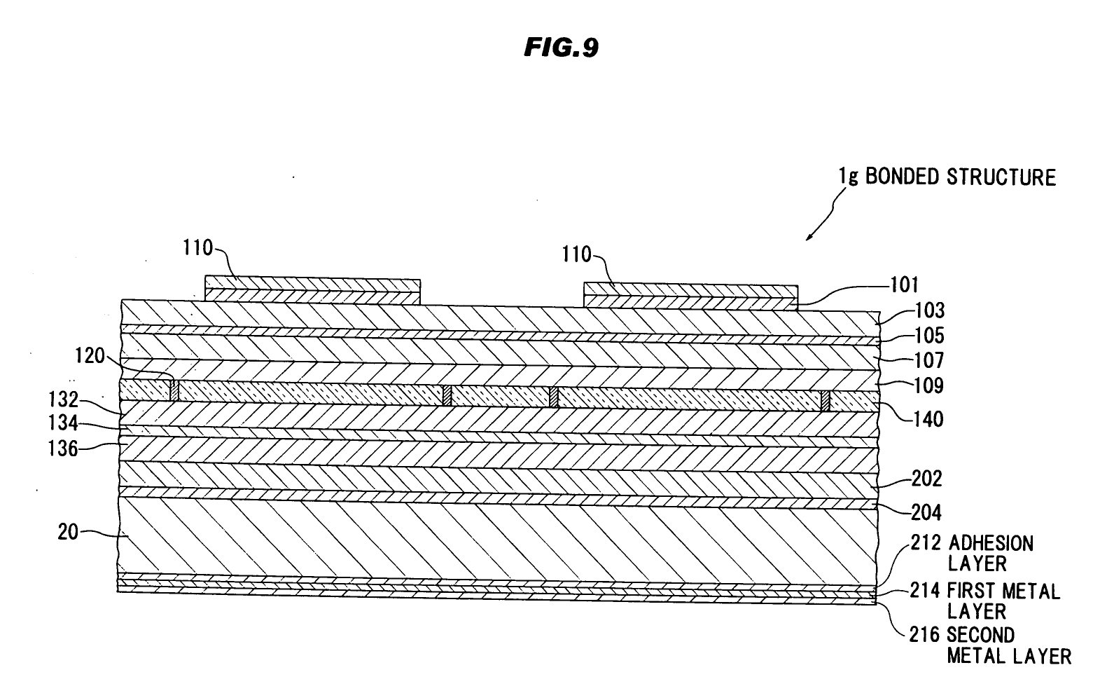

Next, as shown in FIG. 9, the adhesion layer 212, the first metal layer 214, and the second metal layer 216 are formed in this order by vacuum deposition on the back surface of the supporting substrate 20 (on the surface opposite to the surface where the contact electrode 204 of the supporting substrate 20 is provided). The adhesion layer 212 comprises a material having a good adhesion property with the supporting substrate 20, e.g. Ti. In addition, the first metal layer 214 comprises e.g. Al. The second metal layer 216 comprises e.g. Au. Thereby, a bonded structure 1g in which the first metal layer 214 and the second metal layer 216 are formed on the back surface of the supporting substrate 20 via the adhesion layer 212.

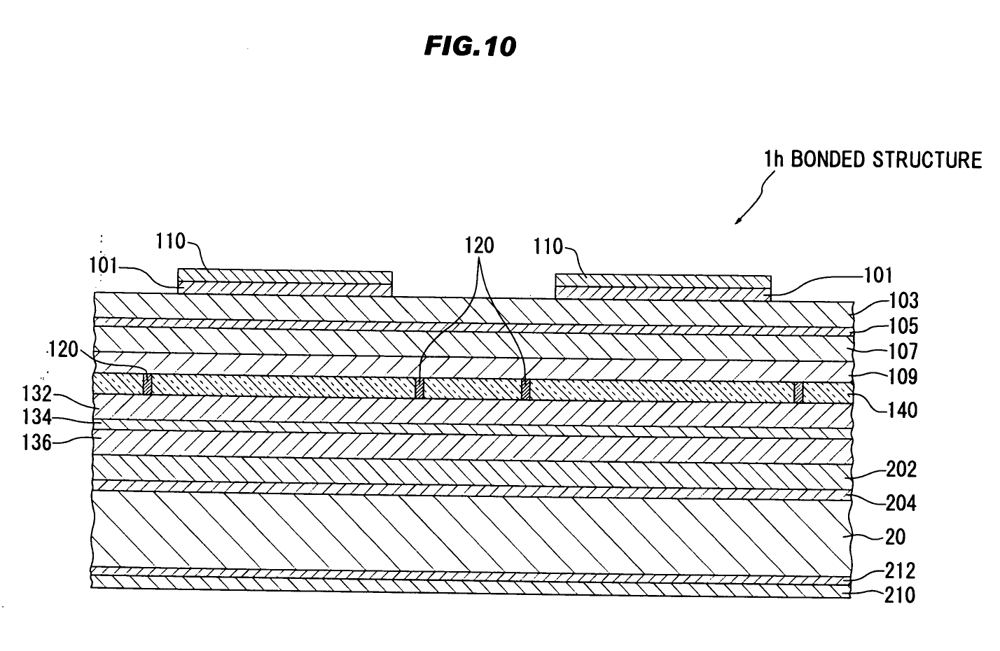

Subsequently, alloying process (alloy process) is performed on the bonded structure 1g, thereby progressing alloying reaction between the first metal layer 214 and the second metal layer 216. As an example, the alloy process is carried out on the bonded structure 1g by heating the bonded structure 1g to a temperature of 400° C. in a nitrogen atmosphere as an inert atmosphere, and keeping it at the temperature of 400° C. for five minutes. More concretely, this alloy process may be carried out by installing the bonded structure 1g on a tray of graphite, and introducing the bonded structure 1g installed on the tray into an alloying equipment comprising an upper heater and a lower heater provided independently from the upper heater, and heated to the temperature of 400° C. According to this alloy process, the back surface electrode 210 which is an alloy layer made by alloying the first metal layer 214 and the second metal layer 216 is formed on the back surface of the supporting substrate 20, as shown in FIG. 10, thereby providing a bonded structure 1h. In addition, the adhesion layer 212 remains as the adhesion layer 212 even after the alloy process, and bonds the back surface electrode 210 to the supporting substrate 20. Namely, in this preferred embodiment, the alloying reaction does not occur substantially between and the supporting substrate 20 and the first metal layer 214 as well as the second metal layer 216 by the existence of the adhesion layer 212, while the alloying reaction progresses between the first metal layer 214 and the second metal layer 216.

In addition, the adhesion layer 212 in this preferred embodiment has a function of securing the adhesion between the supporting substrate 20 and the first metal layer 214 as well as the second metal layer 216 before the alloy process. After the alloy process, the adhesion layer 212 bonds the back surface electrode 210 to the supporting substrate 20, and functions as the electrode together with the back surface electrode 210. In addition, it is possible to suppress the metallic material composing each of the first metal layer 214 and the second metal layer 216 from propagating into the side of the supporting substrate 20, by providing the adhesion layer 212 between the first metal layer 214 and the supporting substrate 20. Accordingly, the alloying reaction between the first metal layer 214 and the second metal layer 216 is preferentially progressed.

Successively, the pad electrode 115 is formed on a part of the surface of the surface electrode 110, more concretely on the circular electrode by the photo lithography method and the vacuum deposition. For example, the pad electrode 115 is formed by depositing Ti and Au in this order on the surface of the circular electrode of the surface electrode 110. In addition, the alloy process is not carried on the pad electrode 115 for the purpose of securing an enough bonding strength between the surface of the pad electrode 115 and wire for feeding an electric power to the light emitting device 1.

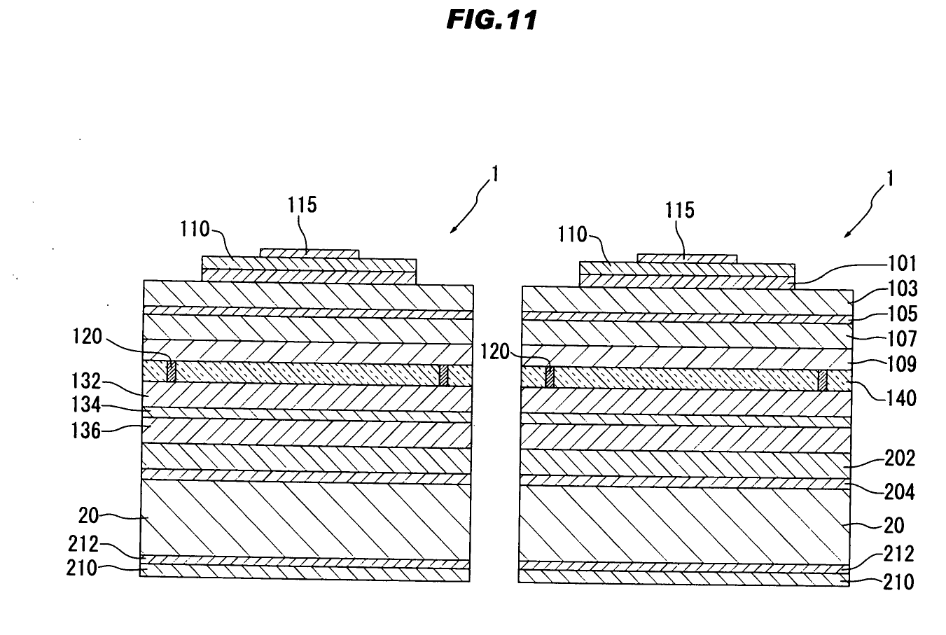

Thereafter, the bonded structure 1h is device-isolated by using a dicing equipment having a dicing blade. In this preferred embodiment, the device-isolation process comprises a half-cut step of cutting the bonded structure 1h from a surface side of the n-type cladding layer 103 to the bottom until a half depth of the bonded structure 1h in a thickness direction, and a full-cut step of completely cutting a part remained in the half-cut step after the half-cut step. Namely, the device is isolated by two stages according to the device-isolation process in this preferred embodiment. At the full-cut step in this preferred embodiment, the back surface electrode 210 including the alloy having a hardness higher than a hardness of Au is cut. Thereby, a plurality of the light emitting devices 1 are formed as shown in FIG. 11.

The light emitting device 1 fabricated by the process shown in FIG. 2A to FIG. 11 is e.g. a light emitting diode (LED) with a configuration of a substantially rectangular with a device size (plane dimensions) of 330 μm×330 μm. Herein, the plane dimensions in the top plan view according to a device design are 350 μm×350 μm. However, the plane dimensions are reduced in length compared with the designed dimensions after passing the half-cut step and the full-cut step due to a blade thickness of the dicing saw of the dicing equipment.

Thereafter, the light emitting device 1 is bonded on a stem such as TO-18 stem by die-bonding with using the electrically conductive material, and the surface electrode 110 and a predetermined region of the TO-18 stem are electrically connected by a wire of e.g. Au. Characteristics of the light emitting device 1 can be evaluated by feeding the electric current from outside to the pad electrode 115 via the wire.

### (Variation of the Fabrication Process)

The back surface electrode 210 in the preferred embodiment is formed by carrying out the alloy process after forming the adhesion layer 212, the first metal layer 214, and the second metal layer 216 on the back surface of the supporting substrate 20. In a variation, for example, a metal layer comprising an alloy material comprising a material for forming the first metal layer 214 and a material for forming the second metal layer 216 may be formed on the adhesion layer 212 instead of the first metal layer 214 and the second metal layer 216.

### (Effect of the Preferred Embodiment)

In the light emitting device 1 in the preferred embodiment, an alloy layer formed from the first metal layer 214 and the second metal layer 216 is used as the back surface electrode 210. Since this alloy layer has the hardness higher than the hardness of Au, it is possible to reduce clogging of diamond abrasives in the diamond blade due to dust of the soft metallic material such as Au during the cutting process using the diamond blade. Namely, the back surface electrode 210 in the preferred embodiment is not a so-called “difficult-to-cut material” that is hardly cut by the dicing, so that it is possible to keeping a high cutting force by the diamond blade. Therefore, according to the light emitting device 1 in the preferred embodiment, it is possible to largely reduce the back surface chipping in the device-isolation process. Therefore, it is possible to provide the light emitting device 1 that can be fabricated in high yield. Further, when the adhesion layer 212 comprises Ti, the adhesion layer 212 is not the difficult-to-cut material in this preferred embodiment either.

In addition, according to the light emitting device I in the preferred embodiment, the alloy material including Au is used for the back surface electrode 210. Therefore, it is possible to provide the light emitting device 1 comprising the back surface electrode 210 with improved resistance against atmospheric oxygen, water, or the like.

### EXAMPLES

### Example 1

In the Example 1, a light emitting device having a structure shown in FIG. 1A and FIG. 1B similarly to the light emitting device 1 fabricated by the fabrication process in the preferred embodiment, and having a following structure was manufactured.

At first, the semiconductor multilayer 10 was formed from an n-type contact layer 101 comprising an n-type (Se-doped) GaAs (a carrier concentration of 5×10¹⁷/cm³), an n-type cladding layer 103 comprising an n-type (Se-doped) (Al_{0.7}Ga_{0.3})_{0.5}In_{0.5}P (a carrier concentration of 5×10¹⁷/cm³), an active layer 105 comprising an undoped (Al_{0.1}Ga_{0.9})_{0.5}In_{0.5}P, a p-type cladding layer 107 comprising a p-type (Mg-doped) (Al_{0.7}Ga_{0.3})_{0.5}In_{0.5}P (a carrier concentration of 1×10¹⁸/cm³), and a p-type contact layer 109 comprising a p-type (Mg-doped) GaP (a carrier concentration of 1×10¹⁸/cm³). A transparent layer 140 was formed from a SiO₂ layer with a thickness of 110 nm. A contact part 120 was formed from AuZn. In addition, a thickness of the contact part 120 is 110 nm similarly to the thickness of the transparent layer 140.

In addition, as a supporting substrate 20, a p-type Si substrate with a resistivity of 0.005 Ω·cm was used. A Au layer with a thickness of 500 nm was used as an adhesion layer side bonding layer 202. A Ti layer with a thickness of 200 nm to 500 nm was used as a contact electrode 204. A Au layer with a thickness of 500 nm was used as a reflecting part side bonding layer 136 of a reflecting part 130. A Pt layer with a thickness of 50 nm was used as a barrier layer 134. An Al layer with a thickness of 400 nm was used as a reflecting layer 132. A width of the contact part 120 was 5 μm. A AuGe layer with a thickness of 50 nm, a Ni layer with a thickness of 10 nm, and a Au layer with a thickness of 300 nm were formed in this order to provide a surface electrode 110. A diameter of a circular electrode of the surface electrode 110 was 100 μm, and a width of a narrow electrode was 10 μm. A Ti layer with a thickness of 30 nm and a Au layer with a thickness of 1000 nm were formed in this order to provide a pad electrode 115. The device size was 330 μm×330 μm in the top plan view.

Furthermore, a back surface electrode 210 was formed by forming a Ti layer with a thickness of 200 nm to 500 nm as an adhesion layer 212, an Al layer with a thickness of 100 nm as a first metal layer 214, and a Au layer with a thickness of 300 nm as a second metal layer 216 in this order, and carrying out the alloy process as described above on these layers. A surface of the second metal layer 216 before the alloy process was gold tinged with metallic luster in visual observation. On the other hand, as for the surface of the back surface electrode 210 after the alloy process, the metallic luster thereof is lost in the visual observation, and the color thereof was changed into a color of dull gray. This shows that the first metal layer 214 and second metal layer 216 were alloyed. In addition, when the thickness of the Au layer is too thin, a forward voltage of the light emitting device in the Example 1 rises by an influence of an oxidation of the alloy which is composed of the first metal layer 214 and the second metal layer 216. Therefore, the volume ratio of the Al and the Au is preferable about 1:X (1≦X<5). In case of the X is five or more, the back surface chipping is occurred because the hardness of the alloy is not enough.

In addition, the device-isolation process was composed of following two-stage isolation process. More concretely, the device-isolation process was carried out by means of two dicing devices. In addition, the bonded structure 1h was attached to a dicing sheet by sticking a side of the back surface electrode 210 on the dicing sheet via an adhesion layer preformed on a surface of the dicing sheet, then put into device-isolation process.

At first, the half-cut step as the first stage of the device-isolation process was performed by using a single-spindle semiautomatic dicing saw (DAD522, a product made by DISCO Corporation) (herein after referred to as “the first dicer”) as a dicing device. Herein, NBC-ZH227J-27HCBC (a product made by DISCO Corporation) was used for a diamond blade for the dicing saw. In this diamond blade, a grit (abrasive) diameter was #4000, and a protrusion of blade edge was substantially 0.560 mm, and a blade thickness was about 29 μm. The cutting conditions of the half-cut step were a spindle revolution was 35000 rpm, a feeding speed was 5 mm/sec, and a cutting depth was 100 μm. Since the thickness of the bonded structure 1 h was about 210 μm, the bonded structure 1h was cut until about a half depth of the bonded structure 1h.

After finishing the half-cut step, the half-cut bonded structure 1h was detached from the first dicer. The detached bonded structure 1h was set in the second dicer, and the full-cut step was carried out. As the second dicer, the dicing saw of the same type as the first dicer (i.e. DAD522 of DISCO Corporation) was also used. However, a diamond blade used for the second dicer was NBC-ZH227J-27HCAA (a product made by DISCO Corporation). In this diamond blade, a grit (abrasive) diameter was #4000, and a protrusion of blade edge was substantially 0.450 mm, and a blade thickness was about 19 μm. The cutting conditions of the full-cut step were a spindle revolution was 30000 rpm, a feeding speed was 5 mm/sec, and a cutting depth was 230 μm. Since the thickness of the bonded structure 1h was about 210 μm, the bonded structure 1h was completely cut by adjusting a cutting depth in the dicing sheet to be about 20 μm. According to this process, the light emitting device 1 of 330 μm×330 μm in the top plan view was provided.

Successively, after finishing the device-isolation process, a plurality of the light emitting devices 1 stuck on the dicing sheet was transferred to another sheet, and another sheet was expanded. In other words, another sheet was stuck on a side of the pad electrode 115 of the light emitting devices 1 that is stuck on the adhesion layer of the dicing sheet in the state that the side of the pad electrode 115 was located downwardly. After transferring the light emitting devices 1 to another sheet, another sheet was isotropically pulled to be expanded. Thereafter, a condition of the back surface chipping of the light emitting devices 1 was observed.

As a result, an occurrence frequency of the back surface chipping in plane of the wafer was equal to or less than 1%. Further, an amount of the back surface chipping was extremely small, in which a chipping width was within 10 μm. Since the plane dimensions of the light emitting device 1 was 330 μm×330 μm, a ratio of the back surface chipping amount to an area in the top plan view of the light emitting device 1 was suppressed to around 3%. Herein, a forward voltage of the light emitting device in the Example 1 was around 2.0V, and evaluated as good.

### Example 2

A light emitting device in Example 2 has a configuration similar to the configuration of the light emitting device in the Example 1, except the material composing the first metal layer 214 and the material composing the second metal layer 216 are different from those in the light emitting device in the Example 1. Therefore, a detailed explanation of the configuration of the light emitting device in the Example 2 is omitted except difference.

In the Examples 2, the material composing the first metal layer 214 and the material composing the second metal layer 216 were respectively changed as shown in TABLE 1. TABLE 1 shows a result of visual observation of the back surface chipping in each back surface electrode and an evaluation result of electric characteristic (forward voltage).

### Comparative Example 1

As a comparative example 1, a light emitting device having a configuration similar to the Example 2 except a back surface electrode composed of Al/Ge alloy was prepared.

TABLE 1

| | Back surface | Occurrence | Maximum | |
|---|---|---|---|---|
| | electrode | frequency of | width | Forward |
| | structure (except | back surface | of back surface | voltage |
| | adhesion layer) | chipping | chipping | (V) |
| Example 2 | Au/Ge alloy | 1% or less | 10 μm or less | 2.04 |
| | Au/Zn alloy | 1% or less | 10 μm or less | 2.04 |
| | Au/Si alloy | 1% or less | 10 μm or less | 2.03 |
| | Au/Be alloy | 1% or less | 10 μm or less | 2.03 |
| | Au/Sn alloy | 1% or less | 10 μm or less | 2.03 |
| Comparative | Al/Ge alloy | 1% or less | 10 μm or less | 2.45 |
| example 1 | | | | |

As clearly shown in TABLE 1, the occurrence frequency of the back surface chipping was small and the forward voltage of the light emitting device was low, namely good for all the light emitting devices comprising the back surface electrode 210 including Au. However, in the light emitting device comprising the back surface electrode composed of Al/Ge alloy and including no Au (Comparative example 1), the forward voltage was a higher than the forward voltage of the light emitting devices in the Example 2. As to a cause of this result, it is assumed that at least a surface of the Al/Ge alloy composing the back surface electrode was oxidized, thereby forming an oxide film on the surface of the back surface electrode. Therefore, it is preferable that the material composing the back surface electrode includes Au.

### Comparative Example 2

A light emitting device in comparative example 2 has a configuration similar to the configuration of the light emitting device in the Example 1, except the adhesion layer comprising Ti is not provided between the back surface electrode and the supporting substrate. Therefore, a detailed explanation of the configuration of the light emitting device in the comparative example 2 is omitted except difference.

In the comparative example 2, twenty one (21) pieces of the bonded structure 1h in which the adhesion layer was not provided were manufactured. The bonded structure 1h was stuck on the dicing sheet to carry out the device-isolation process. As a result, the back surface electrode comprising Au/Al alloy was exfoliated in ten (10) pieces of samples during the sticking process. As to a cause of this result, it is assumed that the alloying reaction between Au and Al progresses preferentially to the alloying reaction or diffusional reaction between Au and/or Al and the supporting substrate 20. In addition, it was confirmed that the good cutting state was realized similarly to the Example 1 when the device-isolation process was carried out on the sample in which the back surface electrode was not exfoliated.

Herein, the electrical characteristic of the light emitting device sample, in which the back surface electrode was not exfoliated and the device-isolation was appropriately performed, was evaluated. As a result, the forward voltage was 2.03V that was a good value similarly to the Example 1. This result shows that it is possible to provide the light emitting device which can be used in practical use if the back surface electrode was not exfoliated. However, in the comparative example 2, a rate of the exfoliation of the back surface electrode due to the absence of the adhesion layer is extremely, so that it is preferable to provide the adhesion layer on the back surface of the supporting substrate 20.

### Variation of the Examples

In the Examples 1 and 2, two single spindle-type semiautomatic dicing saw were used together in the device-isolation process. However, double spindle-type blade dicer may be used. In addition, the diamond blade is not limited to the type used in the Examples, and other type diamond blade may be used.

Although the invention has been described, the invention according to claims is not to be limited by the above-mentioned embodiments and examples. Further, please note that not all combinations of the features described in the embodiments and the examples are not necessary to solve the problem of the invention.

What is claimed is:

1. A light emitting device, comprising:
a semiconductor multilayer structure having a first semiconductor layer of a first conductivity type, a second semiconductor layer of a second conductivity type different from the first conductivity type, and an active layer sandwiched between the first semiconductor layer and the second semiconductor layer;
a reflecting layer provided at a side of one surface of the semiconductor multilayer structure, the reflecting layer reflecting a light emitted from the active layer;
a supporting substrate provided at an opposite side of the reflecting layer with respect to the side of the semiconductor multilayer structure, the supporting substrate supporting the semiconductor multilayer structure via a metal bonding layer;
an adhesion layer provided at a surface of the supporting substrate at an opposite side with respect to a side of the metal bonding layer; and
a back surface electrode provided to contact with a surface of the adhesion layer at an opposite side with respect to a surface contacting to the supporting substrate, the back surface electrode comprising an alloy of different metals.

2. The light emitting device according to claim 1, wherein the semiconductor multilayer structure is supported by the supporting substrate via a transparent layer provided on the reflecting layer,
wherein the transparent layer comprises an interface electrode penetrating through the transparent layer to electrically connect the semiconductor multilayer structure with the reflecting layer.

3. The light emitting device according to claim 1, wherein the adhesion layer comprises Ti for fixing the supporting substrate with the back surface substrate.

4. The light emitting device according to claim 3, wherein the back surface electrode has a hardness higher than a hardness of Au.

5. The light emitting device according to claim 4, wherein the back surface electrode comprises an alloy of Au and at least one material selected from a group consisted of Al, Sn, Si, Zn, Be, and Ge.
